(19) United States
(12) Patent Application Publication
(10) Pub. No.: US 2005/0126766 A1
(43) Pub. Date: Jun. 16, 2005

(54) Nanostructure augmentation of surfaces for enhanced thermal transfer with improved contact

(75) Inventors: Ju-Hyung Lee, San Jose, CA (US); Nasreen G. Chopra, Belmont, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Koila,Inc., Sunnyvale, CA (US)

(21) Appl. No.: 10/944,485

(22) Filed: Sep. 16, 2004

Related U.S. Application Data
(60) Provisional application No. 60/560,180, filed on Apr. 6, 2004.
(60) Provisional application No. 60/544,709, filed on Feb. 13, 2004.
(60) Provisional application No. 60/532,244, filed on Dec. 23, 2003.
(60) Provisional application No. 60/503,591, filed on Sep. 16, 2003.
(60) Provisional application No. 60/503,612, filed on Sep. 16, 2003.
(60) Provisional application No. 60/503,613, filed on Sep. 16, 2003.
(60) Provisional application No. 60/503,638, filed on Sep. 16, 2003.

(51) Int. Cl. H05K 7/20

(52) U.S. Cl. 165/133; 165/185

(57) ABSTRACT

Nanostructures provide improved contact to augment heat-exchange surfaces of various devices or structures. In one embodiment, an article of manufacture has a body having a heat-exchanging surface and nanostructures disposed on the heat-exchanging surface. The nanostructures are arranged to enhance thermal transfer between said body and an object distinct from said body and may be arranged to form a substantially continuous film. Examples of suitable nanostructures include carbon and/or boron nitride nanotubes, which may be grown on the heat-exchanging surface.

### CROSS-REFERENCES TO RELATED APPLICATIONS

This application claims the benefit of the following six provisional U.S. patent applications:
Application No. 60/503,591, filed Sep. 16, 2003, entitled “Nano-Material for System Thermal Management”;
Application No. 60/503,612, filed Sep. 16, 2003, entitled “Oriented Nano-Material for System Thermal Management”;
Application No. 60/503,613, Sep. 16, 2003, entitled “Nano-Material Thermal and Electrical Contact System”;
Application No. 60/532,244, filed Dec. 23, 2003, entitled “Nanotube Augmentation of Heat Exchange Structure”;
Application No. 60/544,709, filed Feb. 13, 2004, entitled “Nano-Material Thermal Management System”; and
Application No. 60/560,180, filed Apr. 6, 2004, entitled “Heat Transfer Structure.”

This application incorporates by reference for all purposes the entire disclosures of the following seven provisional U.S. patent applications:
Application No. 60/503,591, filed Sep. 16, 2003, entitled “Nano-Material for System Thermal Management”;
Application No. 60/503,612, filed Sep. 16, 2003, entitled “Oriented Nano-Material for System Thermal Management”;
Application No. 60/503,638, filed Sep. 16, 2003, entitled “System for Developing Production Nano-Material”;
Application No. 60/503,613, Sep. 16, 2003, entitled “Nano-Material Thermal and Electrical Contact System”;
Application No. 60/532,244, filed Dec. 23, 2003, entitled “Nanotube Augmentation of Heat Exchange Structure”;
Application No. 60/544,709, filed Feb. 13, 2004, entitled “Nano-Material Thermal Management System”; and
Application No. 60/560,180, filed Apr. 6, 2004, entitled “Heat Transfer Structure.”

The following five regular U.S. patent applications (including this one) are being filed concurrently, and the entire disclosures of the other four are incorporated by reference into this application for all purposes.
Application No. ______, filed Sep. 16, 2004, entitled “Nano-Composite Materials for Thermal Management Applications” (Attorney Docket No. 022353-000110US);
Application No. ______, filed Sep. 16, 2004, entitled “Nanostructure Augmentation of Surfaces for Enhanced Thermal Transfer with Increased Surface Area” (Attorney Docket No. 022353-000210US);
Application No. ______, filed Sep. 16, 2004, entitled “Nanostructure Augmentation of Surfaces for Enhanced Thermal Transfer with Improved Contact” (Attorney Docket No. 022353-000220US);
Application No. ______, filed Sep. 16, 2004, entitled “System and Method for Developing Production Nano-Material” (Attorney Docket No. 022353-000310US); and
Application No. ______, filed Sep. 16, 2004, entitled “Nano-Material Thermal and Electrical Contact System” (Attorney Docket No. 022353-000410US).

### BACKGROUND OF THE INVENTION

The present invention relates in general to thermal management, and in particular to nanostructure augmentation of surfaces for enhanced thermal transfer.

Electronic devices such as microprocessors or other integrated circuits devices generate heat as they operate, and excessive heat can lead to device failure. Heat sinks are frequently employed to transfer heat away from a device into the surrounding environment, thereby maintaining the device temperature within its operational limits. A typical heat sink is constructed of aluminum, copper or another metal with high thermal conductivity and has one surface adapted to make thermal contact with the device (typically with the flat top surface of an integrated circuit package) and an opposing surface that includes fins or similar features with high ratios of surface area (SA) to volume (V) so as to increase the surface area exposed to the environment for a given footprint. In some cases, a thermally conductive adhesive is used to bond the heat sink to the device package for improved thermal contact. During device operation, a thermal gradient is established as heat from the device (which is hotter than the heat sink) is absorbed into the heat sink at the device-contacting surface while circulation of ambient air keeps the opposing “dissipation” surface relatively cool. Thus, the heat sink passively removes heat from the device for as long as the thermal gradient is maintained. Heat sinks are sometimes further supplemented with fans to increase air circulation over the dissipation surface area while the device is operating, thereby improving the convective cooling efficiency.

This conventional thermal management technology, which has been effective for many years, has its limitations. As the number and density of heat generating elements (e.g., transistors) packed into devices has increased, the problem of heat dissipation has become a critical consideration in device and system design. It would therefore be desirable to provide improved thermal management technologies suitable for use with electronic devices as well as other applications.

### BRIEF SUMMARY OF THE INVENTION

Embodiments of the present invention provide nanostructure augmentation of surfaces of thermally active devices (i.e., any device that generates, dissipates, collects or otherwise transfers heat to or from any other device or fluid medium). In some embodiments, increased surface area for convective heat transfer is obtained by sparsely coating a surface with nanostructures such as nanotubes or bundles of nanotubes so that air or other cooling fluid can flow between the nanotubes or bundles. In other embodiments, improved thermal contact is obtained by densely coating a surface with nanotubes or bundles of nanotubes.

According to one aspect of the present invention, an article of manufacture includes a body having a first heat-exchanging surface and first nanostructures disposed on the first heat-exchanging surface. The first nanostructures are arranged to enhance thermal transfer between said body and an object distinct from said body. In some embodiments, the first nanostructures may be nanotubes (e.g., carbon and/or boron nitride nanotubes) that may be grown onto the first heat-exchanging surface. In some embodiments, the nanostructures may form a substantially continuous film. The body may be made of any material, including but not limited to metals (e.g., copper, aluminum, or alloys thereof), composite materials, plastics, and ceramics.

According to a further aspect of the present invention, a structure for enhancing thermal transfer between an object and a region of fluid distinct from the object includes a body having a first surface adapted to contact the object and a second surface adapted to contact the fluid and nanostructures disposed on said first surface and arranged so as to enhance thermal transfer between said body and the object. In some embodiments, the second surface may include a plurality of macroscopic fins extending outward therefrom. The nanostructures may be, e.g., nanotubes that may form a substantially continuous film. The body, which may be made of a variety of materials, may have various shapes; for instance, the body may be shaped as a heat sink, a heat pipe, a microfluidic cooling structure, and so on.

According to a still further aspect of the present invention, a package for a heat generating device includes a housing adapted to enclose the heat generating device, the housing having an inner surface and an outer surface, and first nanostructures disposed on at least a portion of the inner surface and arranged to enhance thermal transfer between the heat generating device and the housing. In some embodiments, the nanostructures are electrically insulating nanotubes, such as boron nitride nanotubes. The heat generating device may include an integrated circuit or any other type of heat generating device.

According to yet another aspect of the present invention, a method is provided for augmenting a heat-exchanging surface of a first object. Nanostructures are applied to the heat-exchanging surface of the first object, where said nanostructures are arranged to enhance a thermal transfer process between the first object and a second object distinct from said first object. For example, the nanostructures may include nanotubes, and the nanotubes may be applied, e.g., by growing the nanotubes on the heat-exchanging surface. In some embodiments, the nanotubes form a substantially continuous film.

A wide variety of devices may incorporate aspects of the present invention. Examples include heat sinks for electronic, optical or mechanical devices, but the invention is not limited to these devices.

The following detailed description together with the accompanying drawings will provide a better understanding of the nature and advantages of the present invention.

### BRIEF DESCRIPTION OF THE DRAWINGS

FIGS. 1A-1H illustrate convective nano-coatings using nanotubes according to embodiments of the present invention;

FIG. 2 illustrates a heat sink having nano-coatings according to an embodiment of the present invention;

FIG. 3 illustrates another heat sink having nano-coatings according to an embodiment of the present invention;

FIG. 4 illustrates a cross section of an integrated circuit device having a heat sink integrated into its packaging according to an embodiment of the present invention;

FIGS. 5A-5B illustrates relative form factors of a conventional heat sink compared to a heat sink according to an embodiment of the present invention;

FIGS. 6A-6C illustrate conductive nano-coatings using nanotubes according to embodiments of the present invention; and

FIG. 7 illustrates a device package with enhanced heat-exchange surfaces according to an embodiment of the present invention.

### DETAILED DESCRIPTION OF THE INVENTION

Overview and Terminology

Embodiments of the present invention provide nanostructures that can improve thermal transfer into or out of an object. The term “nanostructure,” or nanoscale structure, as used herein denotes a structure with at least one dimension that is on the order of nanometers (e.g., from about 1 to 100 nm); one or more of the other dimensions may be larger and may be microscopic (from about 10 nm to a few hundred micrometers) or macroscopic (larger than a few hundred micrometers). The nanostructures can be applied to the surface of any device into or out of which heat is to be transferred, including heat sinks, packaging materials for semiconductor devices, and a wide variety of other devices. In some embodiments, the nanostructures are arranged so as to increase the area of a heat-exchanging surface without increasing the footprint; such arrangements can promote convective heat transfer between the object and a fluid medium to which the heat-exchanging surface is exposed. In other embodiments, the nanostructures are arranged so as to increase a thermal contact area between the object and another object.

For thermal management applications, nanostructures having high thermal conductivity are advantageously used to promote heat transfer into or out of the surface to which they are applied. In preferred embodiments, the nanostructures include nanotubes having very high thermal conductivity. Nanotubes are best described as long, thin cylindrically shaped, discrete fibril structures whose diameters are on the order of nanometers. Nanotubes can exhibit lengths up to several hundred microns; thus their aspect ratios can exceed 300. The aspect ratio can be well controlled using process conditions as is known in the art. The terms “single-wall” or “multi-wall” as used to describe nanotubes refer to nanotube structures having one or more layers of continuously ordered atoms where each layer is substantially concentric with the cylindrical axis of the structure; the nanotubes referred to herein may include single-walled and/or multi-walled nanotubes.

Nanotubes have theoretically and experimentally been shown to have high thermal conductivity along the axis of the nanotube. The thermal conductivity of carbon nanotubes, for example, has been measured at around 3000 W/m*K (theoretical calculations indicating conductivities as high as 6000 W/m*K might be achievable), as compared to conventional thermal management materials such as aluminum (247 W/m*K) or copper (398 W/m*K).

Nanotubes in embodiments of the present application may be made of a variety of materials including carbon or boron nitride (BN). The electrical properties of BN nanotubes are particularly well suited to applications where electrical isolation as well as thermal conduction is required because all chiralities of BN nanotubes are semiconductors with a very large bandgap and can therefore act as electrical insulators in many applications. It will be appreciated that other materials may also be substituted.

Nanotubes can be synthesized in various ways including arc-discharge, laser ablation, or chemical vapor deposition (CVD) processes and the like. Particular synthesis techniques are not critical to the present invention. As is known in the art, many of these techniques involve depositing a catalyst material onto a substrate and growing a cluster, or bundle, of nanotubes on the catalyst. Nanotubes can be grown with their axes in a desired orientation by applying a suitable electric field during nanotube synthesis, e.g., in a plasma CVD chamber. Since nanotubes generally grow in clusters, it is to be understood that where the present description refers to nanotubes, clusters (or bundles) of nanotubes may also be used to realize aspects of the invention.

In other embodiments, other types of nanostructures may be used in addition to or instead of nanotubes. Examples of such nanostructures include nanorods, nanowires, nanofibers, nanocrystals, fullerenes, and other nanoscale structures such as chains of nanocrystals or fullerenes. In some embodiments, a combination of different nanostructures may be used, e.g., a combination of boron nitride and carbon nanotubes or a combination of nanotubes with nanocrystals.

In accordance with the present invention, nanostructures are disposed on surfaces of various objects to or from which heat is to be transferred in order to enhance heat exchange between the object and some other object or medium. As used herein, “disposed on” a surface encompasses any techniques by which a nanostructure may be placed or held in contact with a surface, including growth of the nanostructure on the surface, dusting or coating of the surface with the nanostructures, transfer application of the nanostructures onto the surface, chemical bonding, adhesive bonding, van der Waals bonding, and so on. Nanostructures disposed on a surface are referred to generally herein as a “nano-coating”; this term denotes only that the surface is wholly or partially covered by nanostructures and is not intended to imply continuous coverage.

The type and arrangement of nanostructures in a nano-coating can be optimized for various applications. For example, in some embodiments (referred to herein as “convective” nano-coatings), the nano-coatings are optimized for increased surface area within a given footprint; in other embodiments (referred to herein as “conductive” nano-coatings), the nano-coatings are optimized for improving the continuity of a thermal contact area between two surfaces that may have small-scale irregularities. In addition, the nano-coatings may provide improved heat exchange due to other properties of the nano-structures such as color (which can enhance radiative heat transfer) and/or high thermal conductivity.

Examples of nanostructure coatings and objects to which such coatings will now be described. It is to be understood that these examples are illustrative and not limiting of the invention.

Convective Nano-Coatings

Convective heat transfer refers generally to the exchange of heat between a solid object and a fluid medium, such as air, water, or any other fluid. It is well known in the art that convective heat transfer can be made more efficient by increasing the “working” surface area exposed to the fluid relative to the total volume of the object.

In accordance with an aspect of the present invention, a “convective nano-coating” can be applied to a surface so as to increase the working surface area with negligible effect on volume. The convective nano-coating advantageously includes nanostructures with high aspect ratios, such as nanotubes, nanorods, or nanowires, and the nanostructures are preferably spaced apart such that fluid can flow between adjacent nanostructures. Convective nano-coatings may also provide other benefits. For example, carbon or boron nitride nanotubes have high thermal conductivity and can enhance the transfer of heat between the body of the object and the nanotube-augmented surface. In addition, the convective nano-coating may effectively darken the surface of the object, improving its thermal performance as a radiator or absorber of heat.

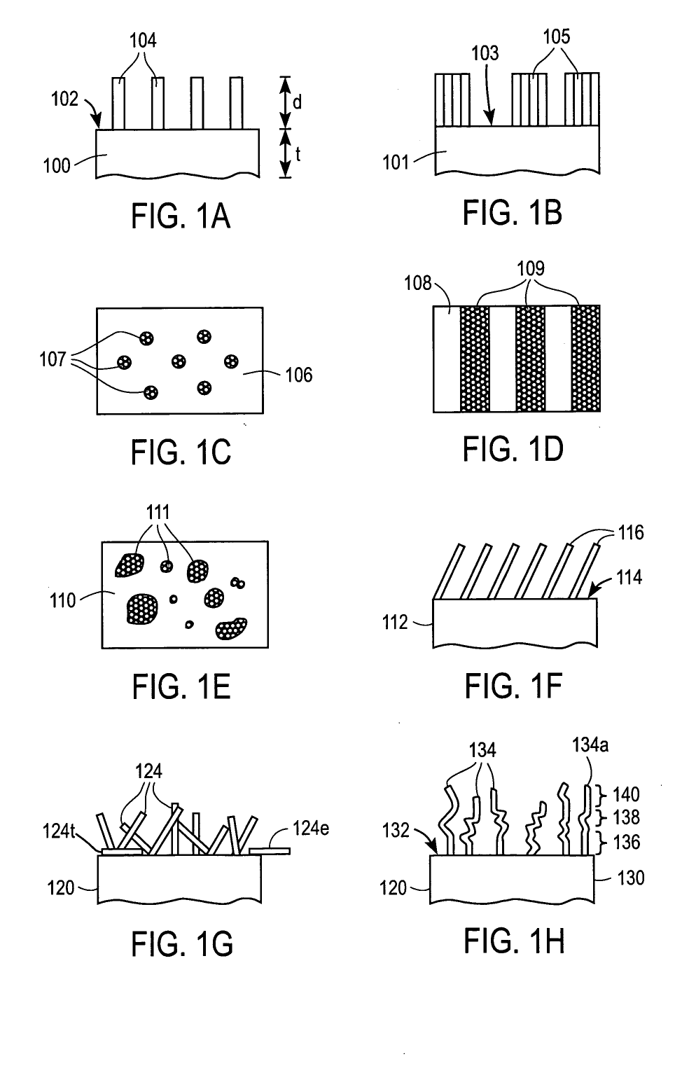

FIGS. 1A-1D illustrate convective nano-coatings using nanotubes according to embodiments of the present invention. In FIG. 1A, a surface 102 of an object 100 (seen in side view) has nanotubes 104 disposed thereon. Object 100 may be any object to or from which heat transfer is desired and may be made of any material on which nanotubes can be disposed. Examples include copper, aluminum, titanium, indium, nickel, magnesium, graphite, iron, stainless steel, other metal alloys, plastics, ceramics, and a variety of other materials; further examples are described below. Surface 102 is shown herein as planar and generally flat, but may have any shape, including curved shapes and shapes with nanoscale, microscopic or macroscopic features. Nanotubes 104 can be made of any suitable material with high thermal conductivity including but not limited to carbon or boron nitride.

Nanotubes 104 are advantageously spaced apart by some distance (e.g., up to 1 mm) so that air or another cooling fluid can circulate between the nanotubes. The density may be tuned to optimize thermal behavior of object 100 for a particular application, and the present invention is not limited to any particular density. For example, nanotubes 104 may form a substantially continuous and dense film of nanotubes, they may form spaced-apart bundles that may be distributed in a pattern or with random spacing, they may be individual spaced-apart nanotubes, where the spacing again may be patterned or random.

It is to be understood that the drawings herein are not to scale (except where specifically noted); in particular, the aspect ratio of nanotubes 104 and nanotube bundles 105 is typically significantly higher than that shown (e.g., on the order of 100 or more). Each nanotube 104 increases the effective area of surface 102 by 2 πrh and occupies a footprint of πr², where r is the radius of the nanotube (e.g., on the order of 1 nm) and h is the height (e.g., on the order of 1-100 μm).

While the surface area of one nanotube is small in relation to the surface area of macroscopic objects, in practice a very large number 104 of nanotubes can be disposed on a surface 102 so that the total increase in effective surface area for a given surface footprint can be substantial. For example, suppose that nanotubes 104 are distributed on surface 102 with a density of 10⁴ per square micrometer; the increase in surface area would be about a factor of 30,000. At this density, nanotubes 104 cover less than 1/10⁶ of surface 102; thus the surface area increase could go even higher, e.g., up to about 10⁶ given current nanotube dimensions.

At the same time, the increase in volume is negligible. The volume of a nanotube (πr² h) is on the order of 10⁻⁴ μm³, so even at high density, nanotubes add very little to the volume of typical macroscopic objects.

Further, it should be noted that nanotubes 104 can increase the effective area of surface 102 with a small or even negligible increase in the overall form factor of the object. For example, the length (dimension l) of nanotubes 104 might be 10-100 μm. If object 100 is a typical macroscopic object, with a thickness (dimension t) of 1 mm or more, the increase in overall thickness is on the order of 1-10% or less. In general, for larger objects the fractional increase in form factor is even smaller.

Nanotubes 104 may be disposed on surface 102 using a variety of methods. In one embodiment, surface 102 may have a patterned catalyst material deposited thereon, using techniques known in the art. Nanotubes 104 can then be grown using a CVD process in the presence of an electric field or plasma. As is known in the art, the electric field can be used to control the direction of nanotube growth so that nanotubes 104 will be generally aligned. It is to be understood that the alignment of nanotubes 104 along a common axis may be imperfect; such arrangements are referred to herein as being “generally aligned.” In one generally aligned configuration, a significant portion (e.g., 40% or more) of the nanotubes are aligned to each other with a mean angular deviation of 30° or less.

In some embodiments, the exposed tips of nanotubes 104 may be specially treated for improved thermal conductivity. For example, after nanotubes 104 are grown (on surface 102 or elsewhere), they may be treated, e.g., by exposing one or both ends of the nanotubes to an oxygen plasma or energetic oxygen that etches away any exposed closed ends, opening the nanotubes. After this treatment, a film of thermally conductive material such as copper, aluminum or indium, can be deposited on the nanotube tips if desired, or the tips may be left open. Further details related to suitable treatment of nanotube ends can be found in above-referenced Application No. ______ (Attorney Docket No. 022353-000410US).

In some embodiments, nanotubes 104 may be realized using nanotube bundles. FIG. 1B illustrates, in side view, an object 101 with a surface 103 that has nanotube bundles 105 disposed thereon. Like object 100 of FIG. 1A, object 101 may be any object to or from which heat transfer is desired and may be made of any material on which nanotubes can be disposed; surface 103 may have any shape. Each nanotube bundles 105 contains a number of closely spaced nanotubes. The perimeter of a bundle on surface 103 may be generally circular or may have any other shape, including rectangular, elongated, or irregular shapes. The number of nanotubes in a bundle 105 depends on the transverse dimension of the bundle (i.e., a dimension transverse to the length of the bundle), which may be, e.g., between about 10 nm and 1 mm or even larger, as well as on the spacing of adjacent nanotubes within the bundle, which may be, e.g., between about 1 nm and 10 nm between outer walls. The spacing of nanotubes in a bundle 105 is advantageously smaller than the spacing between adjacent bundles 105, which may be, e.g., anywhere in the range from about 10 nm to about 1 mm. In general, wherever individual nanotubes are referred to herein, it is to be understood that bundles of nanotubes could be substituted unless otherwise stated.

The nanotubes or nanotube bundles may be arranged on the surface in a variety of ways and may have any spacing. For example, FIGS. 1C-1E are top views of surfaces with convective nano-coatings according to embodiments of the present invention. In FIG. 1C, a surface 106 has regularly spaced nanotubes (or nanotube bundles) 107 disposed thereon. In FIG. 1D, a surface 108 has elongated nanotube bundles 109 disposed thereon; the bundles are spaced apart laterally. These elongated nanotube bundles 109 may have macroscopic transverse dimensions in either or both transverse directions. In FIG. 1E, a surface 110 has nanotube bundles 111 (some of which may be “degenerate” bundles with only one nanotube) that vary as to size and position. Such variation may be random or may have any desired pattern. In all of these configurations, an increase in the effective surface area for a given footprint can be achieved to the extent that fluid can flow between the nanotubes.

The nanotubes (or nanotube bundles) are not restricted to any particular orientation relative to the surface. For example, FIG. 1F illustrates a second object 112 having a surface 114 with nanotubes 116 disposed thereon. Nanotubes 116, which might also be realized as nanotube bundles, are generally aligned with their axes at an oblique angle to surface 114. Such angles can be achieved, e.g., by applying a suitably oriented electric field (or plasma) within a CVD chamber during nanotube growth.

In other embodiments, the nanotubes might not be aligned at all. For example, FIG. 1G illustrates, in side view, a third object 120 having a surface 122 with nanotubes 124 disposed thereon. Nanotubes 124 are randomly oriented with respect to each other and with respect to surface 122. Thus, the axis of a nanotube 124 may meet surface 122 at any angle from 0° to 90°, and the orientation angle of one nanotube 124 may be independent of any other nanotube. It should be noted that even “tangential” nanotubes 124t, 124e, which have axes at a 0° angle to surface 122, can provide some thermal enhancement due to their high thermal conductivity and/or color and/or small increase in the effective surface area. Additionally, tangential nanotube 124e is shown as extending beyond an edge of surface 122, for a further increase in the surface area with negligible effect on footprint if surface 122 is macroscopic. Randomly oriented nanotubes 124 can be grown onto surface 124, or grown separately and applied to surface 124, e.g., using dusting or transfer techniques.

Further, nanotubes that are not straight might also be used. FIG. 1H illustrates, in side view, a fourth object 130 having a surface 132 with nanotubes 134 disposed thereon. Nanotubes 134 are “kinked” along all or part of their length. For instance, nanotube 134a has a bottom straight section 136 that is aligned approximately normal to surface 132, a middle kinked section 138 in which the nanotube is bent in various directions (e.g., in a zigzag pattern), and a top straight section 140 that is approximately parallel to bottom straight section 136. Nanotube 134b is kinked along substantially its entire length. Kinked nanotubes 134 can be created, e.g., by varying an electric field magnitude and/or direction within a CVD chamber at various stages during nanotube growth. For a given total nanotube length, kinked nanotubes 134 will tend to provide a larger surface area than a straight nanotube.

It will be appreciated that the convective nano-coatings described herein are illustrative and that variations and modifications are possible. For example, other nanostructures that provide increased surface area, such as nanorods, nanowires, or nanocrystals (which can create bumps on the surface, adding area), might be used in addition to or instead of nanotubes in a convective nano-coating. In some embodiments, nanorods and/or nanowires made of thermally conductive metals such as aluminum, copper, nickel and/or indium may be used.

In general, nanotube synthesis techniques known in the art may be used to fabricate any of the above-described nano-coatings in accordance with the present invention. For example, in the case where the nano-coating is made from nanotubes, after making or procuring a device that has a target surface to which the nano-coating is to be applied, a suitable catalyst material (such as nickel, cobalt or iron) is deposited on regions of the surface where the nano-coating is desired, and the device is placed in a CVD chamber and nanotubes are grown onto the device in the region of the catalyst. An electric field may be applied in the CVD chamber during nanotube growth to align the nanotubes in a desired orientation.

In other embodiments, nanotubes or other nanostructures may be synthesized separately, using techniques known in the art, then transferred to the target surface, e.g., by dusting the surface with a powder of the nanostructures. These or other techniques can be used to construct a wide variety of devices with nanotubes or other nanostructures attached to a target surface to facilitate heat transfer at that surface. All fabrication techniques referred to herein are illustrative, and any technique for disposing nanotubes or other nanostructures on a surface of an object may be used to provide nano-coatings in accordance with the present invention.

Applications of Convective Nano-Coatings

Convective nano-coatings may be applied to any object to or from which efficient convective heat transfer is desirable. Some examples will now be described.

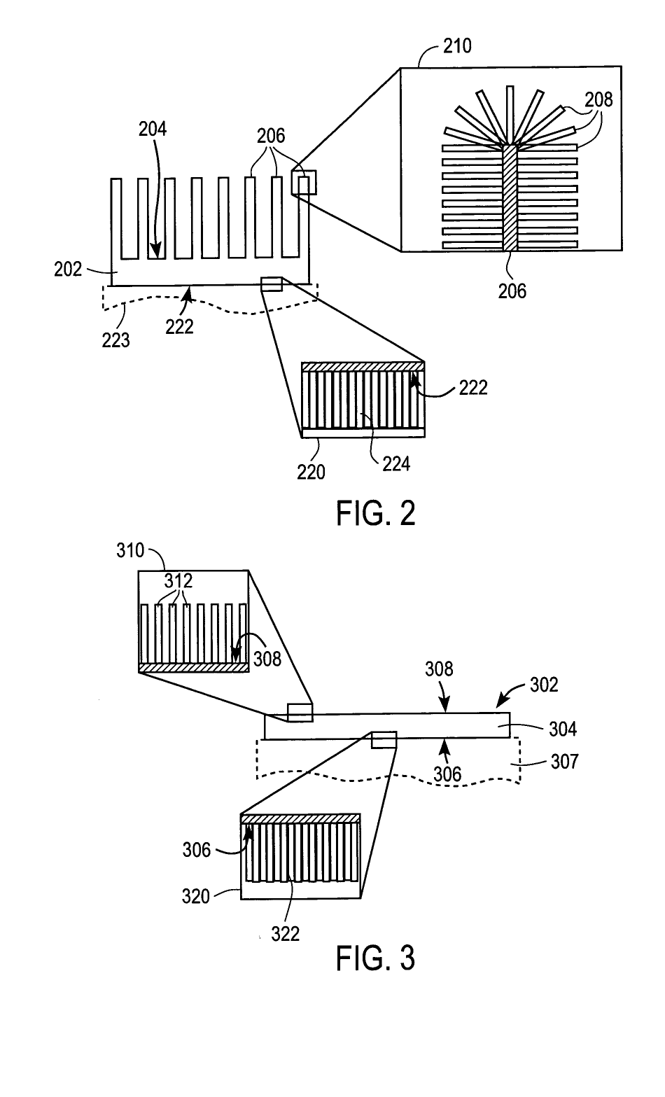

One application for convective nano-coatings is in the field of heat sinks for electronic or other heat generating devices. FIG. 2 illustrates a heat sink 202, which can be, e.g., a conventional aluminum or copper heat sink. Heat sink 202 has an upper surface 204 adapted to dissipate heat into the surrounding environment via convection. Surface 204 includes fins 206 with high ratios of surface area to volume; fins 206 may have, e.g., conventional plate, pin, and/or post shapes and may be arranged in a conventional manner. Thus, heat sink 202 may appear to be identical to conventional heat sinks in terms of overall form factor and weight.

Unlike conventional heat sinks, however, heat sink 202 has a convective nano-coating of nanotubes 208 disposed on the surfaces of fins 206 as shown in inset 210. (As with all drawings herein, inset 210 is not to any particular scale.) Nanotubes 208, which may be realized as nanotube bundles, can be made of any suitable material with high thermal conductivity including carbon or boron nitride. As described above, nanotubes 208 are advantageously spaced apart by some distance (e.g., up to 1 mm) so that air or another cooling fluid can circulate between the nanotubes.

Heat sink 202 has substantially higher cooling efficiency than a conventional heat sink due to the presence of nanotubes 208. As described above, nanotubes 208 can substantially increase the area of surface 204 and thus the heat dissipation performance of heat sink 202. For example, with nanotube spacing on the order of 100 nm, surface area can be increased by a factor of around 10,000. Accordingly, heat sink 202 can dissipate considerably more heat than its conventional counterparts.

In general, heat sink 202 may be made of any material, including but not limited to aluminum, copper, and any other conventional heat sink materials. Other examples of suitable heat sink materials include various base materials into which a material with high thermal conductivity (such as graphite, diamond crystals, diamond particles and/or diamond dust) has been dispersed. Within the scope of the present invention, existing heat sinks can be “retrofitted” with a convective nano-coating to improve their performance.

In some embodiments, heat sink 202 may be made of a nano-composite material in which nanostructures having high thermal conductivity, such as carbon or BN nanotubes, are dispersed into a matrix or base material, such as a metal (e.g., aluminum or copper), metal alloy, plastic, thermoplastic or thermosetting resin, epoxy or ceramic material (e.g., aluminum nitride). A fuller description of suitable nano-composite material structures and examples of devices that can be fabricated therefrom can be found in above-referenced Application No. ______ (Attorney Docket No. 022353-000110US). In accordance with the present invention, surfaces of heat sinks or other thermal transfer devices made of such nano-composite materials can be coated with nanotubes to further improve thermal transfer into or out of such devices.

It will be appreciated that heat sink 202 is illustrative and that variations and modifications are possible. The macroscopic fins may be of any size, number and configuration, and may include any combination of plate, post, and/or pin shapes. The convective nano-coating may be varied, e.g., using any of the example coatings described above with reference to FIGS. 1A-1D.

In some embodiments, heat sink 202 may have a fan mounted thereon to promote movement of air (or other cooling fluid) around the fins. Such a fan and mounting may be of generally conventional design.

As noted above, a heat sink 202 with fins of conventional size can have substantially higher cooling efficiency than conventional heat sinks. In an alternative embodiment, the fin size can be reduced to provide adequate thermal performance for a particular application while reducing the form factor of the heat sink. In some embodiments, macroscopic fins can be entirely eliminated.

FIG. 3 illustrates one such embodiment. A heat sink 302 has a body 304, which may be made of conventional heat sink materials (e.g., aluminum or copper) or nano-composite materials as described in above-referenced Application No. ______ (Attorney Docket No. 022353-000110US). Bottom surface 306 is adapted for contacting a heat generating device 307 (shown in phantom), and top surface 308 is adapted to be exposed to the environment. Top surface 308, which has no fins or other macroscopic protrusions characteristic of conventional heat sinks, has a convective nano-coating of nanotubes 312 (which may be realized as nanotube bundles) as shown in inset 310. As described above with reference to FIGS. 1A-D, nanotubes 312 are advantageously spaced apart to promote convection. Nanotubes 312 may be regarded as “nanofins” that increase the surface area without macroscopic protrusions.

It will be appreciated that heat sink 302 may have a significantly smaller form factor than conventional heat sinks of comparable cooling efficiency. For example, while conventional macroscopic fins may extend for centimeters above a heat sink body, nanotubes 312 extend only hundreds of microns (up to about 1 mm). Further, the body portion 304 of heat sink 302 can be made substantially thinner than conventional heat sink bodies; in some embodiments, the thickness of body portion 304 can be on the order of millimeters or a hundred microns or even less. This reduction in form factor can provide enhanced cooling for applications where compactness is critical (e.g., cellular phones, personal digital assistants, laptop computers, etc.).

Like conventional heat sinks, heat sink 302 may have a fan mounted thereon to promote movement of air or other cooling fluid around the nanofins (nanotubes 312 shown in FIG. 3). Such a fan and mounting may be of generally conventional design, or may be miniaturized as appropriate to the size of a particular embodiment of heat sink 302.

Heat sink 302 is illustrative and variations and modifications are possible. For example, the dimensions of body 302 may be expanded or contracted to any scale. The convective nano-coating may also be varied, e.g., using any of the example coatings described above with reference to FIGS. 1A-1D.

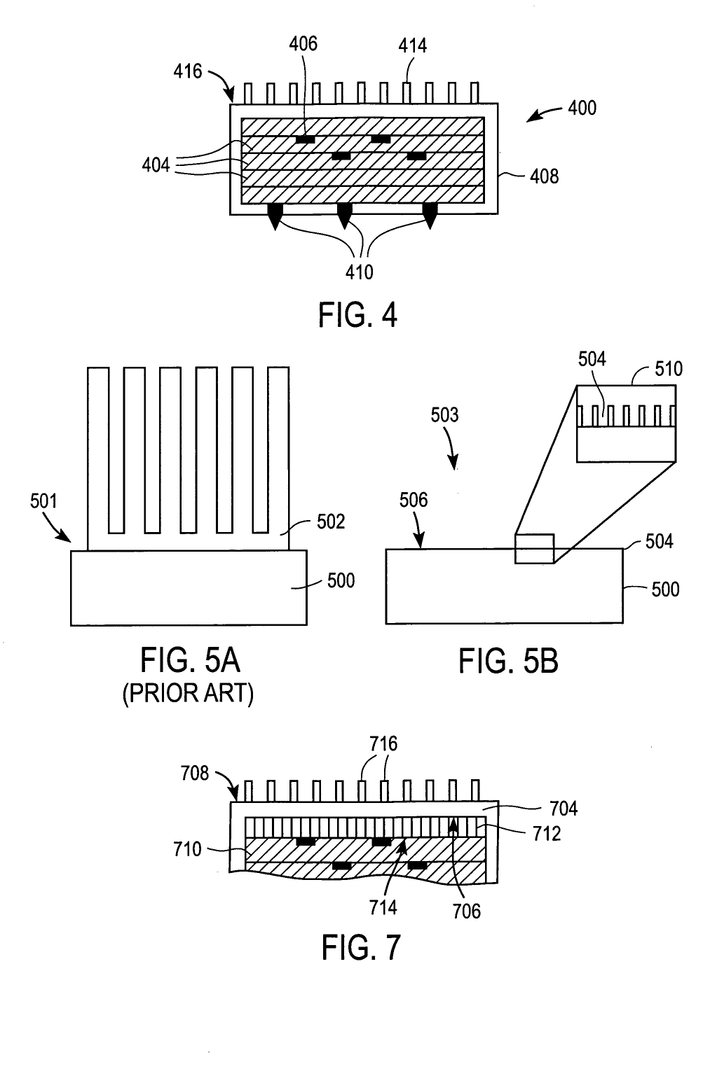

In yet another embodiment, a heat sink with nanofins can be integrated into the package of a semiconductor integrated circuit (IC) device. FIG. 4 illustrates a cross section of an IC device 400. Device 400 includes one or more layers 404 of semiconductor material (e.g., silicon), with the layers having various circuit components 406 (e.g., transistors, capacitors, conductive pathways, etc.) formed therein or thereon. Insulating material and appropriate conductive pathways may be placed between layers 404. Layers 404 are housed within a hermetic package 408 that protects layers 404 from environmental exposure and possible damage. Package 408 may be fabricated using various materials known in the art, such as nickel-coated copper. Metal pins 410 extend through the bottom surface 412 of package 408, and device 400 may be electrically connected to other components via pins 410, e.g., by mounting device 400 and other components on a conventional printed circuit board.

In accordance with an embodiment of the present invention, a convective nano-coating of nanotubes 414 (which may be realized as nanotube bundles) are grown or otherwise disposed on the top surface 416 of package 408 to aid in dissipation of heat produced by device 400 during its operation. If package 408 contains significant amounts of nickel, the nickel of package 408 can provide sufficient catalyst for growth of nanotubes 414. Alternatively, a liquid or sputtered catalyst can be applied to top surface 416, and the catalyst may be patterned as desired (e.g., using any of the patterns of FIGS. 1C-1E). Nanotubes 414 may be grown on surface 416 of package 408 prior to insertion of layers 404 and final sealing of package 408, or they may be added later.

As described above, nanotubes 414 may be advantageously spaced apart in a “nanofin” configuration so as to promote convective cooling of top surface 416. Accordingly, package 408 may itself act as a heat sink for device 400 and may eliminate the need for a separate heat sink, thereby reducing the weight and bulk of products that incorporate a device in package 408.

FIGS. 5A-5B illustrate a form factor advantage that can be gained from using package 408. FIG. 5A illustrates an assembly 501 consisting of a device 500 with a conventional heat sink 502 mounted thereon. Heat sink 502, which may be considerably taller than device 500, adds considerably to the vertical size of assembly 501 and may in fact act as a lower bound on the vertical size. FIG. 5B illustrates, on the same scale as FIG. 5A, an assembly 503 consisting of the same device 500 with a convective nano-coating 504 of nanotubes grown or otherwise disposed on surface 506 in place of a conventional heat sink. Convective nano-coating 504 is effectively invisible in this view and is shown clearly only under magnification, e.g., as illustrated in inset 510 (which is not to scale). Thus, the vertical form factor of assembly 503 is, in effect, determined by device 500 itself, not by a heat sink.

Package 408 is illustrative and variations and modifications are possible. For example, the dimensions may be expanded or contracted to any scale. The convective nano-coating may also be varied, g., using any of the example coatings described above with reference to FIGS. 1A-1D.

It is to be understood that the foregoing examples are illustrative and not limiting of the invention. Convective nano-coatings as described herein may be applied to any surface of an object where enhanced convective cooling (or heating) is desired. For example, a backside surface of an LCD (liquid crystal display) screen or a CCD (charge coupled device) could have a convective nano-coating applied thereto to improve thermal stability of the device by increasing heat exchange with the environment. As another example, the outer surface of a conventional heat pipe, or selected portions of the outer surface, could be augmented with a convective nano-coating to improve thermal transfer between the heat pipe and its environment. Surfaces of microfluidic cooling structures can also be augmented with convective nano-coatings. As yet another example, a convective nano-coating could be applied to appropriate surfaces of larger-scale heating or cooling devices such as an automobile radiator, a heat exchanger in a refrigerator, and so on.

Conductive Nano-Coatings

Conductive heat transfer refers generally to the exchange of heat between two objects that are placed in thermal contact with each other. It is well known in the art that the efficiency of conductive heat transfer depends in part on the size of the area of thermal contact. In general, microscopic irregularities in the contact surfaces of the objects can significantly affect the quality of the thermal contact between them.

In accordance with another aspect of the present invention, a “conductive nano-coating” can be applied to a contact surface of an object so as to improve its ability to make thermal contact with an opposing surface of another object. The conductive nano-coating can enhance the thermal transfer between surfaces in various ways. For instance, nanotubes have high thermal conductivity, which can facilitate conduction between the objects. In addition, nanotubes provide a conformal coating with some degree of resiliency; the contours of the nano-coating can deform as needed to make continuous contact with the opposing surface. Further, nanotubes can move relative to each other, to relieve thermal stress that may develop at the interface. Other nanostructures with similar properties may be substituted for nanotubes. In some embodiments, the nanostructures are densely packed (e.g., as a film) on the contact surface so as to maximize the total area of contact; in other embodiments, there may be spaces between some or all of the nanostructures.

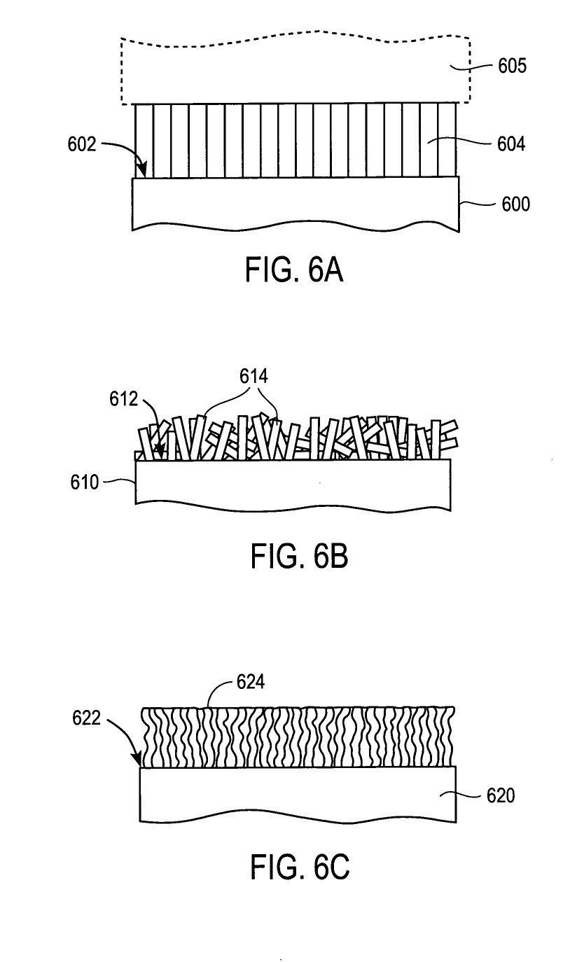

FIGS. 6A-6C illustrate conductive nano-coatings using nanotubes according to embodiments of the present invention. In FIG. 6A, a contact surface 602 of an object 600 has a dense coating of nanotubes disposed thereon. Object 600 may be any object to or from which conductive heat transfer is desired and may be made of any material on which nanotubes can be disposed; in addition to the examples given above, further examples are described below. Surface 602 is shown herein as planar and generally flat, but may have any shape, including curved shapes and shapes with nanoscale, microscopic or macroscopic features. Nanotubes 604, which may be realized as nanotube bundles as described above, can be made of any suitable material with high thermal conductivity including carbon or boron nitride.

In this embodiment, nanotubes 604 are advantageously densely packed or formed as a single large bundle or a substantially continuous film so that gaps between adjacent nanotubes are minimized. Nanotubes 604 may be formed using any of the fabrication techniques referred to above (including growing the nanotubes 604 directly onto surface 602 or growing nanotubes 604 separately and then applying them to surface 602) or other techniques. In one embodiment, nanotubes 604 are generally aligned. The exposed tips of nanotubes 604 may be specially treated as described above to improve heat transfer between the tips of nanotubes 604 and the opposing surface of an object 605 (shown in phantom). A thermally conductive film of a material compatible with the opposing surface (e.g., the same material as the opposing surface) may be applied as described above.

The nanotubes (or other nanostructures) of a conductive nano-coating may be arranged in various ways and may have any orientation. In some embodiments, nanotubes 604 may be generally aligned to be perpendicular to surface 602; in other embodiments, nanotubes 604 might be aligned at an oblique angle (not shown).

In other embodiments, the nanotubes might not be aligned at all. For example, FIG. 6B illustrates a second object 610 having a surface 612 with nanotubes 614 disposed thereon. Nanotubes 614, which in one embodiment form a dense film or mat, are randomly oriented with respect to each other and with respect to surface 612. Thus, the axis of a nanotube 614 may meet surface 612 at any angle from 0° to 90°, and the orientation angle of one nanotube 614 may be independent of any other nanotube. Randomly oriented nanotubes 614 can be grown onto surface 614, or grown separately and applied to surface 614, e.g., using dusting or transfer techniques.

Further, nanotubes that are not straight might also be used. FIG. 6C illustrates a third object 620 having a surface 622 with nanotubes 624 disposed thereon. Nanotubes 624 are “kinked” along all or part of their length, similarly to nanotubes 134 of FIG. 1D described above. Kinked nanotubes are capable of spring-like behavior, and in some embodiments, the presence of kinks in some or all of the nanotubes can enhance the resilience of the nano-coating, leading to improved thermal contact between object 620 and a microscopically uneven opposing surface (not shown).

It will be appreciated that the conductive nano-coatings described herein are illustrative and that variations and modifications are possible. In some embodiments, the density of nanostructures in some conductive nano-coatings may be tuned to control the thermal transfer efficiency of the device; thus, a maximum packing density is not required. In addition, other nanostructures that provide high thermal conductivity and/or resiliency, such as nanorods, nanowires, nanocrystals, or the like might be used in addition to or instead of nanotubes in a conductive nano-coating. In some embodiments, nanorods and/or nanowires made of thermally conductive metals such as aluminum, copper, nickel and/or indium may be used.

Applications of Conductive Nano-Coatings

Conductive nano-coatings may be applied to any object into or out of which efficient conductive heat transfer is desirable. Some examples will now be described.

Referring again to FIG. 2, heat sink 202 has a bottom surface 222 that is adapted to conduct heat away from a heat generating device 223 (shown in phantom). As illustrated in inset 220, a conductive nano-coating of nanotubes 224 can be disposed on bottom surface 222. Nanotubes 224, which may be realized as nanotube bundles, can be made of any suitable material with high thermal conductivity including carbon or boron nitride. As described above, nanotubes 224 are advantageously densely packed to maximize the area of thermal contact between bottom surface 222 and an opposing surface of the heat generating device.

Nanotubes 224 can substantially increase the thermal performance of heat sink 202 by enabling heat to be drawn away from the heat generating device more efficiently. For example, if the heat generating device is a silicon device and good thermal contact is made between the silicon device surface and the nanotubes, thermal transfer efficiency can be improved by about a factor of 3.

It should be noted that the addition of nanotubes 224 to device-contacting surface 222 may eliminate the need for a separate interface material between heat sink 202 and the heat generating device. In conventional apparatus with heat generating devices, surface irregularities of the heat sink or the heat generating device can impede effective thermal contact; this has frequently been solved by placing a flexible (or viscous fluid) interface material with high thermal conductivity between the two. Nanotubes 224 can fill in such surface irregularities sufficiently well that surface 224 of heat sink 202 can simply be placed against a heat generating device without use of other material, thus eliminating a component of an apparatus as well as an assembly step.

Similarly, as shown in FIG. 3, reduced-form-factor heat sink 302 has a bottom surface 306 that is adapted for thermal contact with an opposing surface of a heat generating device 307 (shown in phantom). Inset 320 illustrates a coating of nanotubes 322 that can be applied to surface 306 to improve the quality of the thermal contact. Such a conductive nano-coating can eliminate the need for a separate interface material between surface 306 and the heat generating device without substantially increasing the form factor of heat sink 302.

In some embodiments, body 304 of heat sink 302 may be reduced to a thin film of thermally conductive material with nanotubes disposed on either side of the film. On one side (surface 306), the nanotubes 322 are densely spaced to promote thermal contact for conductive heat transfer, and on the other side (surface 308) the nanotubes 312 are spaced apart to increase the surface area and promote convective heat transfer. Body 304 can be made thin in relation to the length of the nanotubes (e.g., 5 to 10 nm) and may also be flexible or malleable, so that heat sink 302 can be applied to surfaces of arbitrary shape without specific molding or pre-shaping.

FIG. 7 illustrates an application of conductive nano-coatings to a semiconductor device. A semiconductor device package 702 has a top portion 704 with an inner surface 706 and an outer surface 708. Inside package 702 is a semiconductor circuit device 710 that generates heat as it operates. Inner surface 706 has a conductive nano-coating 712 for improving thermal contact between inner surface 706 and a top surface 714 of device 710. In some embodiments, nano-coating 712 is made of boron nitride nanotubes, which are semiconducting (with large bandgaps) in all chiralities and can provide electrical isolation in addition to high thermal conductivity. Outer surface 708 has a convective nano-coating 716, which may contain or consist of, e.g., spaced-apart nanotubes as described above.

In this embodiment, a heat sink is effectively built into the semiconductor device packaging through the presence of nano-coatings 712 and 716. Depending on the thermal properties of the semiconductor device 710 (e.g., how much heat it generates), a separate heat sink might not be necessary. It will be appreciated that packages such as package 702 can advantageously be provided with convective and/or conductive nano-coatings at the time of package manufacture. In other embodiments, nano-coatings 712 and 716 may be customized for a particular semiconductor device 710; for example, conductive nano-coating 712 might be made more dense in areas opposite particularly hot regions of semiconductor device 710 and less dense elsewhere.

It is to be understood that the foregoing examples are illustrative and not limiting of the invention. Conductive nano-coatings as described herein may be applied to any surface of an object where enhanced thermal contact with, or enhanced thermal transfer to or from, another object is desired. As another example, a conductive nano-coating might be applied to the surface of an otherwise conventional printed circuit board where an integrated circuit device is to be mounted, for purposes of enhancing thermal transfer out of the device and into the board. As yet another example, the outer surface of a conventional heat pipe, or selected portions of the outer surface, could be augmented with a conductive nano-coating to improve thermal transfer between the heat pipe and an object (e.g., a heat source) to which a portion of the heat pipe is to be attached. Such coatings may also be used in microfluidic cooling structures as well as other applications.

Conclusion

While the invention has been described with respect to specific embodiments, one skilled in the art will recognize that numerous modifications are possible. For instance, convective nano-coatings and/or conductive nano-coatings in accordance with the present invention may be applied to any elements in electrical, optical or mechanical systems of any size scale.

Further, the terms “convective” and “conductive” are used herein to describe nano-coatings that are optimized for increasing an exposed surface area (as is often desirable for heat exchange between an object and a fluid medium) and nano-coatings that are optimized for enhancing an object-to-object contact surface (as is often desirable for heat exchange between two solid objects). In practice, heat transfer between two objects or between an object and a fluid may occur through a combination of physical processes, including convection, conduction, and/or radiation. A given nano-coating may enhance thermal transfer through any or all of these processes. For instance, nanostructures that are black in color (e.g., nanotubes) may increase radiative heat transfer in addition to any enhancement of convection and/or conduction. Thus, it is to be understood that the nano-coatings described herein are not limited to any particular mechanism for enhancing thermal transfer.

Additionally, in embodiments shown herein, nanotubes (e.g., carbon or boron nitride nanotubes) are used to coat various surfaces. In other embodiments, other types of nanostructures may be used in addition to or instead of nanotubes, including nanorods, nanofibers, nanocrystals, fullerenes, and other nanoscale structures such as chains of nanocrystals or fullerenes. In some embodiments, a combination of different nanostructures may be used, e.g., a combination of boron nitride and carbon nanotubes or a combination of nanotubes with nanocrystals. Nanostructure coatings may be applied to thermal transfer devices having a variety of sizes and shapes and intended for any application.

Thus, although the invention has been described with respect to specific embodiments, it will be appreciated that the invention is intended to cover all modifications and equivalents within the scope of the following claims.

1. An article of manufacture, comprising:
a body having a first heat-exchanging surface; and
a plurality of first nanostructures disposed on said first heat-exchanging surface,
wherein said first nanostructures are arranged to enhance thermal transfer between said body and an object distinct from said body.

2. The article of claim 1 wherein said first nanostructures form a substantially continuous film.

3. The article of claim 1 wherein said first nanostructures include a plurality of nanotubes.

4. The article of claim 3 wherein said nanotubes form a substantially continuous film.

5. The article of claim 3 wherein said nanotubes are grown onto said first heat-exchanging surface.

6. The article of claim 3 wherein said nanotubes are generally aligned along a common axis.

7. The article of claim 6 wherein said common axis is oriented to be substantially normal to the surface of the object.

8. The article of claim 3 wherein said nanotubes are randomly oriented.

9. The article of claim 3 wherein said nanotubes include carbon nanotubes and/or boron nitride nanotubes.

10. The article of claim 5 wherein said nanotubes include single-walled nanotubes and/or multi-walled nanotubes.

11. The article of claim 3 wherein at least one of said nanotubes has a kinked section.

12. The article of claim 1 wherein said nanostructures include nanorods and/or nanowires.

13. The article of claim 12 wherein said nanowires include a nanowire made of a metal.

14. The article of claim 13 wherein said metal is selected from the group consisting of indium, copper, nickel and aluminum.

15. The article of claim 1 wherein said body is composed of at least one of copper, aluminum, a copper alloy or an aluminum alloy.

16. The article of claim 1 wherein said body is composed of a nano-composite material that includes a base material and nanostructures incorporated into the base material.

17. The article of claim 1 wherein said body is composed of a composite material that includes a base material and a second material with high thermal conductivity, said second material being dispersed in said base material.

18. The article of claim 17 wherein said second material is selected from a group consisting of graphite, diamond crystal, diamond particles, and diamond dust.

19. The article of claim 1 wherein said body is composed at least in part of at least one material selected from a group consisting of copper, aluminum, titanium, indium, nickel, magnesium, graphite, iron, and stainless steel.

20. The article of claim 1 wherein said body is composed at least in part of a plastic.

21. The article of claim 1 wherein said body is composed at least in part of a ceramic.

22. A structure for enhancing thermal transfer between an object and a region of fluid distinct from the object, the structure comprising:
a body having a first surface adapted to contact the object and a second surface adapted to contact the fluid;
a plurality of nanostructures disposed on said first surface and arranged so as to enhance thermal transfer between said body and the object.

23. The structure of claim 22 wherein said second surface includes a plurality of macroscopic fins extending outward therefrom.

24. The structure of claim 22 wherein said nanostructures include nanotubes.

25. The structure of claim 24 wherein said nanotubes form a substantially continuous film.

26. The structure of claim 24 wherein said nanotubes include boron nitride nanotubes and/or carbon nanotubes.

27. The structure of claim 24 wherein said nanotubes are generally aligned along a common axis.

28. The structure of claim 27 wherein said common axis is substantially normal to said first surface.

29. The structure of claim 24 wherein said nanotubes are randomly oriented.

30. The structure of claim 22 wherein said body is composed of a nano-composite material that includes a base material and nanostructures incorporated into the base material.

31. The structure of claim 22 wherein said body is composed at least in part of at least one material selected from a group consisting of copper, aluminum, titanium, indium, nickel, magnesium, graphite, iron, and stainless steel.

32. The structure of claim 22 wherein said body is shaped as a heat sink.

33. The structure of claim 22 wherein said body is shaped as a heat pipe.

34. The structure of claim 22 wherein said body is shaped as a microfluidic cooling structure.

35. A package for a heat generating device, the package comprising:
a housing adapted to enclose the heat generating device, said housing having an inner surface and an outer surface; and
a plurality of first nanostructures disposed on at least a portion of said inner surface and arranged to enhance thermal transfer between the heat generating device and said housing.

36. The package of claim 35 wherein the heat generating device comprises an integrated circuit.

37. The package of claim 35 wherein said housing is composed at least in part of nickel-plated copper.

38. The package of claim 35 wherein said nanostructures include nanotubes.

39. The package of claim 38 wherein said nanotubes include electrically insulating nanotubes.

40. The package of claim 38 wherein said nanotubes include boron nitride nanotubes.

41. The package of claim 38 wherein said nanotubes are generally aligned along a common axis.

42. The package of claim 38 wherein said nanotubes are randomly oriented.

43. A method for augmenting a heat-exchanging surface of a first object, the method comprising:
applying a plurality of nanostructures to the heat-exchanging surface of the first object,
wherein said nanostructures are arranged to enhance a thermal transfer process between the first object and a second object distinct from said first object.

44. The method of claim 43 wherein said nanostructures include a plurality of nanotubes.

45. The method of claim 44 wherein said applying step includes growing said plurality of said nanotubes on said heat-exchanging surface.

46. The method of claim 44 wherein said nanotubes form a substantially continuous film.

47. The method of claim 44 wherein said nanotubes are generally aligned along a common axis.

48. The method of claim 47 wherein said common axis is oriented to be substantially normal to the surface of the object.

49. The method of claim 44 wherein said nanotubes are randomly oriented.

50. The method of claim 44 wherein said nanotubes include carbon nanotubes and/or boron nitride nanotubes.

51. The method of claim 43 wherein said nanostructures include nanorods and/or nanowires.

52. The method of claim 51 wherein said nanowires include a nanowire made of a metal.

53. The method of claim 52 wherein said metal is selected from the group consisting of indium, copper, nickel and aluminum.
